(19) United States
(12) Patent Application Publication
(10) Pub. No.: US 2002/0070040 A1
(43) Pub. Date: Jun. 13, 2002

(54) Global positioning system (GPS) receiver assembly

(76) Inventors: James Oyang, Palos Verdes, CA (US); Anchyun Wang, Cerritos, CA (US)

Correspondence Address: ROZSA & CHEN LLP, Suite 1601, 15910 Ventura Boulevard, Encino, CA, 91436-2815, US

(21) Appl. No.: 09/733,337

(22) Filed: Dec. 7, 2000

(51) Int. Cl. H05K 9/00

(52) U.S. Cl. 174/35 R

(57) ABSTRACT

An assembly for a global positioning system (GPS) receiver. The GPS receiver assembly has an outer housing made of a water-resistant material and forming a water-tight enclosure, and an inner shielding box made of a material capable of shielding electromagnetic interference and sized to fit inside the water-tight enclosure and divide the enclosure into an inner compartment and a separated compartment. A first electronic printed circuit board (PCB) of the GPS receiver is positioned within the inner compartment, and a second electronic PCB with an internal antenna of the GPS receiver is positioned within the separated compartment.

### BACKGROUND OF THE INVENTION

1. Field of the Invention

The present invention relates generally to the field of global positioning system (GPS) receivers. More particularly, the present invention relates to the field of assembling a GPS receiver.

2. Description of the Prior Art

Global Positioning System (GPS) receivers are widely used for navigation and precise positioning. Moreover, with the rapid increase of the use of portable GPS receivers by general consumers, it is a trend to make the GPS receivers more compact and light. However, this presents a challenge as to how to reduce and prevent electromagnetic interferences between the electronic components of a GPS receiver when they are confined in a very small housing. In addition, prior art GPS receiver assemblies often require the electronic components and housing members to be assembled by screws or other mechanical means, which is very laborious and time consuming.

It is therefore desirable to provide a GPS receiver assembly that is very light and compact, yet provides sufficient shielding to electromagnetic interference between its electronic components, and also can be assembled by snap-fit without the using of screws.

### SUMMARY OF THE INVENTION

The present invention is a global positioning system (GPS) receiver assembly.

It is an object of the present invention to provide a GPS receiver assembly that is very light weight and compact in size.

It is also an object of the present invention to provide a GPS receiver assembly that has separate internal compartments for reducing and preventing electromagnetic interference between its electronic components.

It is another object of the present invention to provide a GPS receiver assembly that can be snap-fit together without the using of screws or other mechanical means.

It is an additional object of the present invention to provide a GPS receiver assembly that holds it internal electronic printed circuit boards in a suspended manner to reduce shock impact and heat build-up.

It is a further object of the present invention to provide a GPS receiver assembly that provides a water-tight enclosure for it internal electronic components.

Described generally, the present invention is global positioning system (GPS) receiver assembly. The GPS assembly includes an outer housing, an inner shielding box, a first internal electronic printed circuit board (PCB), and a second internal PCB having an internal antenna installed thereon. The outer housing includes a bottom plate and an upper cover made of a water-resistant material, and means for assembling the bottom plate and the upper cover together to form a water-tight enclosure. The inner shielding box is made of a material capable of the enclosure into an inner compartment and a separated compartment. The GPS receiver assembly also includes means for positioning the first PCB within the inner compartment, and means for positioning the second PCB within the separated compartment.

The present invention GPS receiver assembly has many unique features and advantages. It has a structure with separate compartments that is designed to reduce and prevent electromagnetic interference between its electronic components. The structure also holds the internal electronic printed circuit boards of the GPS receiver in a suspended manner to reduce shock impact and heat build-up. The GPS receiver assembly is very light and compact, and can be snap-fit together to provide a water-tight enclosure without the using of screws or other mechanical means.

Further novel features and other objects of the present invention will become apparent from the following detailed description, discussion and the appended claims, taken in conjunction with the drawings.

### BRIEF DESCRIPTION OF THE DRAWINGS

Referring particularly to the drawings for the purpose of illustration only and not limitation, there is illustrated:

FIG. 1 is a perspective view of the present invention global positioning system (GPS) receiver assembly;

FIG. 2 is an exploded perspective view of the present invention GPS receiver assembly; and

FIG. 3 is an enlarged cross-sectional view taken along line 3-3 of FIG. 1.

### DETAILED DESCRIPTION OF THE PREFERRED EMBODIMENTS

Although specific embodiments of the present invention will now be described with reference to the drawings, it should be understood that such embodiments are by way of example only and merely illustrative of but a small number of the many possible specific embodiments which can represent applications of the principles of the present invention. Various changes and modifications obvious to one skilled in the art to which the present invention pertains are deemed to be within the spirit, scope and contemplation of the present invention as further defined in the appended claims.

The present invention is a global positioning system (GPS) receiver assembly. Basically, the GPS receiver assembly includes an outer housing, an inner shielding box, a first internal electronic printed circuit board (PCB), and a second internal PCB having an internal antenna installed thereon. The outer housing includes a bottom plate and an upper cover made of a water-resistant material, where the bottom plate has an upwardly extending periphery lip, and the upper cover having an raised top plate and a downwardly extending circumferential sidewall. The downward sidewall of the upper cover has a double-wall bottom edge for snap-fitting with the periphery lip of the bottom plate to form a water-tight enclosure. The inner shielding box includes a bottom tray and a top shield made of a material capable of shielding electromagnetic interference. The bottom tray is sized to fit inside the water-tight enclosure and has a bottom plate and an upwardly extending circumferential sidewall, and the top shield is sized to fit inside the bottom tray and has a top plate and a downwardly extending circumferential sidewall, to divide the enclosure into an inner compartment and a separated compartment. The GPS receiver assembly further includes means for positioning the first PCB within the inner compartment, and means for positioning the second PCB within the separated compartment.

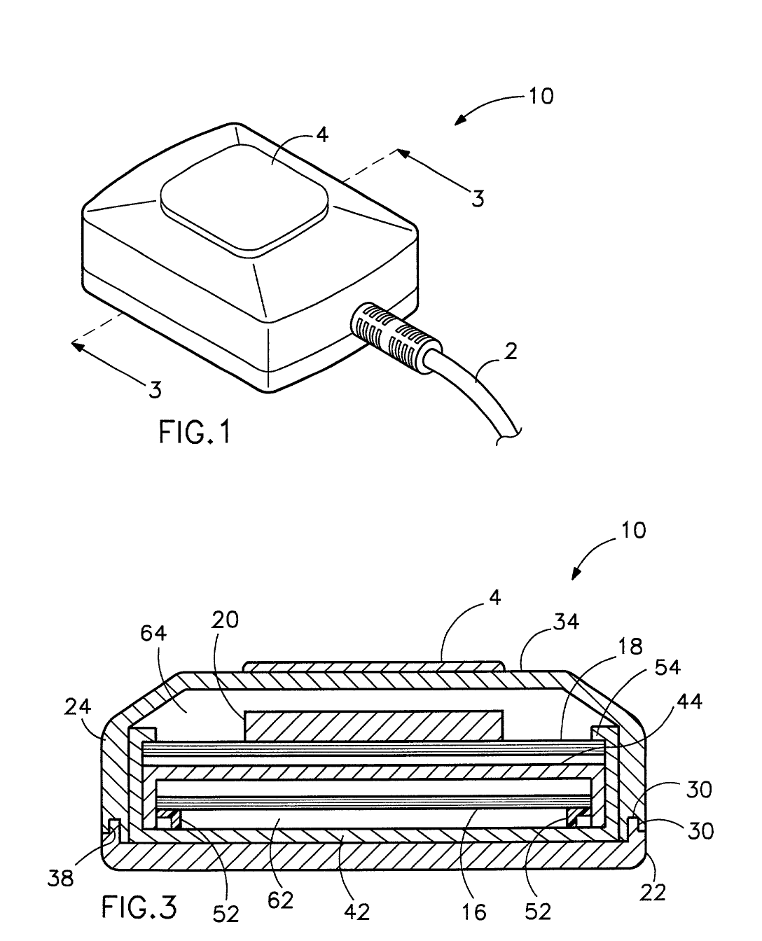

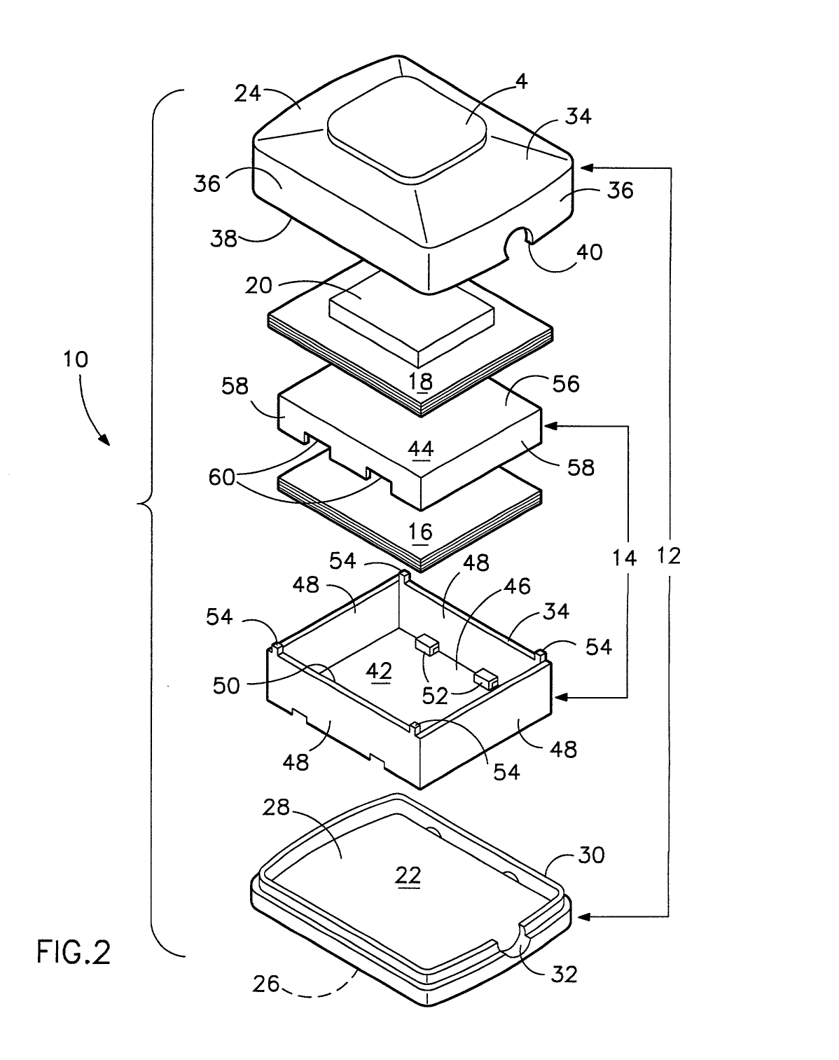

Referring to FIGS. 1, 2 and 3, there is shown at 10 a global positioning system (GPS) receiver assembly. The GPS receiver assembly 10 includes an outer housing 12 and an inner shielding box 14, a first internal electronic printed circuit board (PCB) 16, a second internal PCB 18, and an antenna 20 installed on the second PCB 20.

The outer housing 12 includes a bottom plate 22 and an upper cover 24. The bottom plate 22 has an exterior surface 26, an interior surface 28, an upwardly extending periphery lip 30, and a semicircle aperture 32 located on the lip 30 for accommodating a connection cable 2. The upper cover 24 has a top plate 34 and a downwardly extending circumferential sidewall 36. The sidewall 36 has a slotted double-wall bottom edge 38 with a semicircle aperture 40 also for accommodating the connection cable 2. A logo piece 4 can be affixed externally to the raised portion of the top plate 34 of the upper cover 24. The material, shape and position of the logo piece 4 are designed and arranged to improve the reception sensitivity of the GPS assembly 10.

When the outer housing 12 is assembled, the lip 30 of the bottom plate 22 and the slotted double-wall bottom edge 38 of the upper cover 24 are snap-fit together to form the water-tight enclosure, with the semicircle aperture 40 of the upper cover 24 aligned with the semicircle aperture 30 of the bottom plate 22 for the purpose of accommodating the connection cable 2. By way of example, the bottom plate 22 and the upper cover 24 of the outer housing 12 may be made of plastic or other like water-resistant materials.

The inner shielding box 14 includes a bottom tray 42 and top shield 44 sized to fit inside the outer housing 12. The bottom tray 42 has a bottom plate 46 and an upwardly extending circumferential sidewall 48 with a periphery edge 50. The bottom tray 42 also has spacers 52 on the bottom plate 46 for supporting the first PCB 16, and bendable tips 54 on the periphery edge for suspending and grounding second PCB 18. The top shield 44 is sized to fit inside the bottom tray 42, and has a top plate 56 and the downwardly extending sidewall 58 with notch openings 60 to accommodating the spacers 52 of the bottom tray 42. When the top shield 44 is inserted inside the bottom tray 42, it separates the space enclosed by the outer housing 12 into two separate compartments 62 and 64.

By way of example, the bottom tray 42 and top shield 44 of the inner shielding box 14 may be made of metal or other like materials capable of shielding electromagnetic interferences.

The first PCB 16 is installed within the lower or “inner” compartment 62. The first PCB may consist multiple layers. For example, the bottom and top layers of the first PCB 16 may be electronic components, with a metal ground layer and power layer “sandwiched” there between. The metal ground layer further provides shielding of the electromagnetic interferences between the electronic components at the bottom and top layers of the first PCB 16.

The second PCB 18 is installed within the upper or “separated” compartment 64. The second PCB 18 also may consist multiple layers. For example, the bottom layer of the second PCB 18 may be electronic components, and the top layer of the second PCB may be a metal ground layer, with a metal shield layer and power layer “sandwiched” therebetween. The antenna 20 can be installed on the top layer of the second PCB 18.

When the second PCB 18 is assembled, the bendable tips 54 of the inner shielding box are bent over and attached to, preferably by wielding, the top metal ground layer of the second PCB 18. This arrangement serves many advantageous purposes. First, it suspends the second PCB 18 within the upper compartment 64 such that the electronic components at the bottom layer of the second PCB 18 is not brought into contact with the top shield 44 of the inner shielding box 14. In addition, it provides electrical grounding for the inner shielding box 14. Moreover, the inner metal shield layer of the second PCB now serves to prevent electromagnetic interferences between the electronic components at the bottom layer of the second PCB 18 and the antenna 20.

From the above description it can be seen that when the GPS receiver assembly is finally assembled, the electronic component layers of the PCBs are not only shielded from the outside interferences, but also from the interferences of each other. In addition, the antenna is shielded from the electronic component layers of the PCBs. This arrangement is for the purpose of reducing the electromagnetic interferences and therefore improving the sensitivity of the reception of the antenna and ensuring the proper function of the electronic components.

The present invention conforms to conventional forms of manufacture or any other conventional way known to one skilled in the art, and is of simple construction and is durable and easy to assemble.

Defined in detail, the present invention is a global positioning system (GPS) receiver assembly, comprising: (a) an outer housing, an inner shielding box, a first internal electronic printed circuit board (PCB), and a second internal PCB having an internal antenna installed thereon; (b) said outer housing further comprising a bottom plate and an upper cover made of a water-resistant material, the bottom plate having an upwardly extending periphery lip, the upper cover having an raised top plate and a downwardly extending circumferential sidewall, the downward sidewall having a double-wall bottom edge for snap-fitting with the periphery lip of the bottom plate to form a water-tight enclosure; (c) said inner shielding box further comprising a bottom tray and a top shield made of a material capable of shielding electromagnetic interference, the bottom tray sized to fit inside said water-tight enclosure and having a bottom plate and an upwardly extending circumferential sidewall, and the top shield sized to fit inside the bottom tray and having a top plate and a downwardly extending circumferential sidewall, to divide said enclosure into an inner compartment and a separated compartment; (d) means for positioning said first PCB within said inner compartment; and (e) means for positioning said second PCB within said separated compartment.

Defined broadly, the present invention is a global positioning system (GPS) receiver assembly, comprising: (a) an outer housing, an inner shielding box, a first internal electronic printed circuit board (PCB), and a second internal PCB having an internal antenna installed thereon; (b) said outer housing further comprising a bottom plate and an upper cover made of a water-resistant material, and means for assembling the bottom plate and the upper cover together to form a water-tight enclosure; (c) said inner shielding box being made of a material capable of shielding electromagnetic interference and sized to fit inside said water-tight enclosure and divide said enclosure into an inner compartment and a separated compartment; (d) means for positioning said first PCB within said inner compartment; and (e) means for positioning said second PCB within said separated compartment.

Defined more broadly, the present invention is an assembly for a global positioning system (GPS) receiver having at least one internal electronic circuitry component and an internal antenna, comprising: (a) an outer housing made of a water-resistant material and forming a water-tight enclosure; (b) an inner shielding box made of a material capable of shielding electromagnetic interference and sized to fit inside said water-tight enclosure and divide said enclosure into an inner compartment and a separated compartment; (c) means for positioning said at least one internal electronic circuitry component within said inner compartment; and (d) means for positioning said internal antenna within said separated compartment.

Of course the present invention is not intended to be restricted to any particular form or arrangement, or any specific embodiment, or any specific use, disclosed herein, since the same may be modified in various particulars or relations without departing from the spirit or scope of the claimed invention hereinabove shown and described of which the apparatus or method shown is intended only for illustration and disclosure of an operative embodiment and not to show all of the various forms or modifications in which this invention might be embodied or operated.

The present invention has been described in considerable detail in order to comply with the patent laws by providing full public disclosure of at least one of its forms. However, such detailed description is not intended in any way to limit the broad features or principles of the present invention, or the scope of the patent to be granted. Therefore, the invention is to be limited only by the scope of the appended claims.

What is claimed is:

1. An assembly for a global positioning system (GPS) receiver having at least one internal electronic circuitry component and an internal antenna, comprising:
a. an outer housing made of a water-resistant material and forming a water-tight enclosure;
b. an inner shielding box made of a material capable of shielding electromagnetic interference and sized to fit inside said water-tight enclosure and divide said enclosure into an inner compartment and a separated compartment;
d. means for positioning said at least one internal electronic circuitry component within said inner compartment; and
e. means for positioning said internal antenna within said separated compartment.

2. The assembly for a global positioning system (GPS) receiver as defined in claim 1, wherein said at least one electronic circuitry component is a printed circuit board (PCB).

3. The assembly for a global positioning system (GPS) receiver as defined in claim 1, wherein said outer housing comprises a bottom plate and an upper cover, and means for assembling the bottom plate and the upper cover together to form a water-tight enclosure.

4. The assembly for a global positioning system (GPS) receiver as defined in claim 3, wherein said means for assembling the bottom plate and the upper cover comprises an upwardly extending periphery lip on said bottom plate, and a downwardly extending double-wall bottom edge on said upper cover for snap-fitting with the periphery lip of said bottom plate to form said water-tight enclosure.

5. The assembly for a global positioning system (GPS) receiver as defined in claim 1, wherein said inner shielding box comprises a bottom tray having a bottom p late and an upwardly extending circumferential sidewall, and a top shield sized to fit inside the bottom tray.

6. The global positioning system (GPS) receiver assembly as defined in claim 5, wherein said means for positioning said at least one electronic circuitry component within said inner compartment comprises spaced apart spacers in said bottom tray of said inner shielding box.

7. The global positioning system (GPS) receiver assembly as defined in claim 5, wherein said means for positioning said internal antenna within said separated compartment comprises spaced apart bendable tips on said sidewall of said bottom tray of said inner shielding box for attaching to a means supporting said internal antenna.

8. The global positioning system (GPS) receiver assembly as defined in claim 7, wherein said means supporting said internal antenna is an electronic printed circuit board (PCB).

9. The global positioning system (GPS) receiver assembly as defined in claim 1, wherein said outer housing has an opening for passage of an external cable.

10. The global positioning system (GPS) receiver assembly as defined in claim 1, wherein said outer housing is made of a plastic material.

11. The global positioning system (GPS) receiver assembly as defined in claim 1, wherein said inner shielding box ix are made of a metal material.

12. A global positioning system (GPS) receiver assembly, comprising:
a. an outer housing, an inner shielding box, a first internal electronic printed circuit board (PCB), and a second internal PCB having an internal antenna installed thereon;
b. said outer housing further comprising a bottom plate and an upper cover made of a water-resistant material, and means for assembling the bottom plate and the upper cover together to form a water-tight enclosure;
c. said inner shielding box being made of a material capable of shielding electromagnetic interference and sized to fit inside said water-tight enclosure and divide said enclosure into an inner compartment and a separated compartment;
d. means for positioning said first PCB within said inner compartment; and
e. means for positioning said second PCB within said separated compartment.

13. The global positioning system (GPS) receiver assembly as defined in claim 12, wherein said means for assembling the bottom plate and the upper cover comprises an upwardly extending periphery lip on said bottom plate, and a downwardly extending double-wall bottom edge on said upper cover for snap-fitting with the periphery lip of said bottom plate to form said water-tight enclosure.

14. The global positioning system (GPS) receiver assembly as defined in claim 12, wherein said inner shielding box comprises a bottom tray having a bottom plate and an upwardly extending circumferential sidewall, and a top shield sized to fit inside the bottom tray and having a top plate and a downwardly extending circumferential sidewall.

15. The global positioning system (GPS) receiver assembly as defined in claim 14, wherein said means for positioning said first PCB within said inner compartment comprises spaced apart spacers in said bottom tray of said inner shielding box.

16. The global positioning system (GPS) receiver assembly as defined in claim 14, wherein said means for positioning said second PCB within said separated compartment comprises spaced apart bendable tips on said sidewall of said bottom tray of said inner shielding box for attaching to said second PCB.

17. The global positioning system (GPS) receiver assembly as defined in claim 12, wherein said outer housing has an opening for passage of an external cable.

18. The global positioning system (GPS) receiver assembly as defined in claim 12, wherein said outer housing is made of a plastic material.

19. The global positioning system (GPS) receiver assembly as defined in claim 12, wherein said inner shielding box ix are made of a metal material.

20. A global positioning system (GPS) receiver assembly, comprising:
a. an outer housing, an inner shielding box, a first internal electronic printed circuit board (PCB), and a second internal PCB having an internal antenna installed thereon;
b. said outer housing further comprising a bottom plate and an upper cover made of a water-resistant material, the bottom plate having an upwardly extending periphery lip, the upper cover having an raised top plate and a downwardly extending circumferential sidewall, the downward sidewall having a double-wall bottom edge for snap-fitting with the periphery lip of the bottom plate to form a water-tight enclosure;
c. said inner shielding box further comprising a bottom tray and a top shield made of a material capable of shielding electromagnetic interference, the bottom tray sized to fit inside said water-tight enclosure and having a bottom plate and an upwardly extending circumferential sidewall, and the top shield sized to fit inside the bottom tray and having a top plate and a downwardly extending circumferential sidewall, to divide said enclosure into an inner compartment and a separated compartment;
d. means for positioning said first PCB within said inner compartment; and
e. means for positioning said second PCB within said separated compartment.

21. The global positioning system (GPS) receiver assembly as defined in claim 20, wherein said means for positioning said first PCB within said inner compartment comprises spaced apart spacers in said bottom tray of said inner shielding box.

22. The global positioning system (GPS) receiver assembly as defined in claim 20, wherein said means for positioning said second PCB within said separated compartment comprises spaced apart bendable tips on said sidewall of said bottom tray of said inner shielding box for attaching to said second PCB.

23. The global positioning system (GPS) receiver assembly as defined in claim 20, wherein said outer housing has an opening for passage of an external cable.

24. The global positioning system (GPS) receiver assembly as defined in claim 20, wherein said outer housing are made of a plastic material.

25. The global positioning system (GPS) receiver assembly as defined in claim 20, wherein said inner shielding box ix are made of a metal material.
